(19) United States
(12) Patent Application Publication
(10) Pub. No.: US 2026/0353629 A1
(43) Pub. Date: Nov. 5, 2026

(54) CAPACITORLESS SEMICONDUCTOR MEMORY DEVICE

(71) Applicant: SK hynix Inc., Gyeonggi-do (KR)

(72) Inventors: Won Tae KOO, Gyeonggi-do (KR); Jae Gil LEE, Gyeonggi-do (KR); Mir IM, Gyeonggi-do (KR)

(21) Appl. No.: 19/332,068

(22) Filed: Sep. 18, 2025

(30) Foreign Application Priority Data
Apr. 30, 2025 (KR) 10-2025-0057059

(51) Int. Cl. H10B 12/00

(52) U.S. Cl. CPC H10B 12/00

(57) ABSTRACT

A capacitorless semiconductor memory device includes an underlying layer; a lower insulating layer disposed over the underlying layer; a write transistor disposed over the lower insulating layer; a read transistor disposed over the write transistor; and an upper insulating layer disposed over the read transistor. The write transistor includes a write source electrode; a write channel layer disposed over the write source electrode; a write gate dielectric layer disposed to surround a side surface of the write channel layer; a write gate electrode disposed surround a side surface of the write gate dielectric layer; a write drain electrode disposed over the write channel layer; and a write drain electrode upper barrier layer disposed over the write drain electrode. The write drain electrode upper barrier layer includes a carbon layer.

### CROSS-REFERENCE TO RELATED APPLICATIONS

This patent document claims priority under 35 U.S.C. 119(a) to Korean Patent Application No. 10-2025-0057059, filed on Apr. 30, 2025, which is incorporated herein by reference in its entirety.

### TECHNICAL FIELD

The present disclosure relates to a capacitorless semiconductor memory device.

### BACKGROUND

Semiconductor memory devices have an element for storing data. As the degree of integration of semiconductor memory devices has increased, the proportion of the volume of the capacitor for storing data has concurrently increased significantly. Accordingly, a capacitorless semiconductor memory device has been proposed.

An embodiment of the present disclosure provides a capacitorless semiconductor memory device having a graphene layer.

In accordance with an embodiment of the present disclosure, a capacitorless semiconductor memory device includes an underlying layer; a lower insulating layer disposed over the underlying layer; a write transistor disposed over the lower insulating layer; a read transistor disposed over the write transistor; and an upper insulating layer disposed over the read transistor. The write transistor includes a write source electrode; a write channel layer disposed over the write source electrode; a write gate dielectric layer disposed to surround a side surface of the write channel layer; a write gate electrode disposed to surround a side surface of the write gate dielectric layer; a write drain electrode disposed over the write channel layer; and a write drain electrode upper barrier layer disposed over the write drain electrode. The write drain electrode upper barrier layer includes a carbon layer.

In accordance with an embodiment of the present disclosure, a capacitorless semiconductor memory device includes a lower insulating layer; a write transistor disposed over the lower insulating layer; a read transistor disposed over the write transistor; and an upper insulating layer disposed over the read transistor. The read transistor includes a read gate electrode disposed over a write channel layer of the write transistor; a read gate electrode upper barrier layer disposed over the read gate electrode, the read gate electrode upper barrier layer including a graphene layer; a read gate dielectric layer disposed over the read gate electrode upper barrier layer; a read channel layer disposed over the read gate dielectric layer; a read source electrode disposed to be adjacent to a first side of the read channel layer; and a read drain electrode disposed to be adjacent to a second side surface of the read channel layer.

In accordance with an embodiment of the present disclosure, a capacitorless semiconductor memory device includes a peripheral circuit layer including transistors, vertical contact plugs, and horizontal interconnections, which are disposed over a substrate; and a memory cell layer disposed over the peripheral circuit layer, the memory cell layer including at least one memory cell layer in which a plurality of memory cells are arranged. Each of the memory cells includes a lower insulating layer; a write transistor disposed over the lower insulating layer; a read transistor disposed over the write transistor; and an upper insulating layer disposed over the read transistor. The write transistor includes a write source electrode disposed over the lower insulating layer; a write channel layer disposed over the write source electrode; a write gate dielectric layer disposed to surround a side surface of the write source electrode; a write gate electrode disposed to surround a side surface of the gate dielectric layer; a write drain electrode disposed over the write channel layer; and a graphene layer disposed between the write channel layer and the write drain electrode, or between the write drain electrode and the read transistor.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a circuit diagram of a memory cell of a capacitorless semiconductor memory device according to an embodiment of the present disclosure.

FIG. 2 is a three-dimensional perspective view illustrating a memory cell of a capacitorless semiconductor memory device according to an embodiment of the present disclosure.

FIGS. 3A-3C are longitudinal cross-sectional views schematically illustrating memory cells of capacitorless semiconductor memory devices according to embodiments of the present disclosure.

FIGS. 4A-4C are diagrams illustrating the barrier layers according to embodiments of the present disclosure.

FIG. 4D is a conceptual diagram illustrating hydrogen atoms passing through the pores of the stacked graphene layers.

FIG. 5 is a longitudinal cross-sectional view schematically illustrating a capacitorless semiconductor memory device according to an embodiment of the present disclosure.

### DETAILED DESCRIPTION

Embodiments of the present disclosure are described in detail with reference to the accompanying drawings. Specific structural or functional descriptions of specific embodiments are provided as examples to describe the technical concepts that are disclosed in the present application. However, it should be understood that various other examples or embodiments in accordance with the technical concepts of the present disclosure may be carried out in various forms by those with ordinary skill in the art without departing from the scope of the present disclosure. Hence, the present disclosure is not limited only to the described examples or embodiments.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

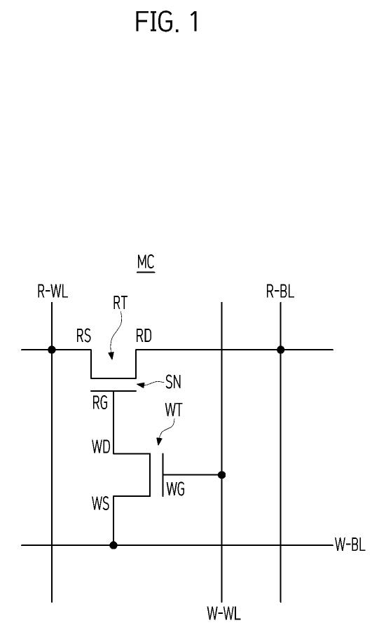

FIG. 1 is a circuit diagram of a memory cell MC of a capacitorless semiconductor memory device according to an embodiment of the present disclosure. Referring to FIG. 1, the memory cell MC of the semiconductor device may include a write transistor WT and a read transistor RT. A write gate electrode WG of the write transistor WT may be electrically connected to a write word line W-WL. A write source electrode WS of the write transistor WT may be electrically connected to a write bit line W-BL. A write drain electrode WD of the write transistor WT may be electrically connected to a read gate electrode RG of the read transistor RT. A read source electrode RS of the read transistor RT may be electrically connected to a read word line R-WL. A read drain electrode RD of the read transistor RT may be electrically connected to a read bit line R-BL.

### Write Operation

A positive (+) voltage may be applied to the write gate electrode WG of the write transistor WT from the write word line W-WL, and a current corresponding to an input data value may be provided to the write source electrode WS from the write bit line W-BL. The current provided to the write source electrode WS may be provided to the write drain electrode WD through a write channel layer of the write transistor WT. The current provided to the write drain electrode WD may be provided to the read gate electrode RG of the read transistor RT as a voltage. Thus, electric charges may be trapped in a gate dielectric layer - for example, a storage node SN - of the read transistor RT. When a positive (+) current is provided to the write drain electrode WD, the electric charge may be trapped in the storage node SN. Thus, a read channel layer of the read transistor RT may have a low resistance state (Logic High, Data 1). When a negative (-) current or a zero (0) current is provided to the write drain electrode WD, the electric charges may be discharged from the storage node SN. Thus, the read channel layer of the read transistor RT may have a high resistance state (Logic Low, Data 0). While the write operation is performing, the read word line R-WL and the read bit line R-BL may be floated or grounded. In an embodiment, the logic H and the logic L may be interpreted in reverse. That is, the logic L may be interpreted as the data 1, and the logic H may be interpreted as the data 0.

### Read Operation

When a current is applied to the read source electrode RS of the read transistor RT from the read word line R-WL, the current may be provided to the read drain electrode RD of the read transistor RT. The current provided to the read drain electrode RD may have a high current value or a low current value according to the data value stored in the storage node SN. Thus, the current provided to the read drain electrode RD may be provided to the read bit line R-BL. The current provided to the read bit line R-BL may be sensed, amplified, and interpreted as data values of the logic high or the logic low in a sense amplifier. While the read operation is performing, the write word line W-WL and the write bit line W-BL may be floated or grounded.

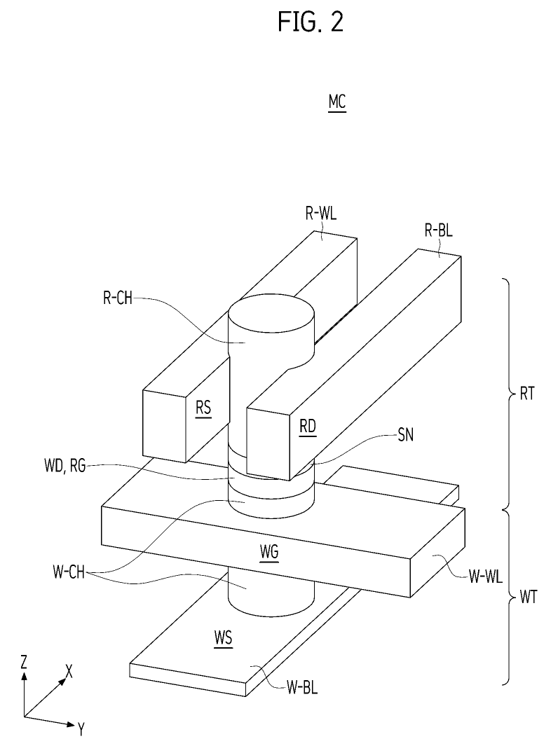

FIG. 2 is a three-dimensional perspective view illustrating a memory cell MC of a capacitorless semiconductor memory device according to an embodiment of the present disclosure. Referring to FIG. 2, the memory cell MC of the capacitorless semiconductor memory device may include a write transistor WT and a read transistor RT which are vertically disposed and stacked.

The write transistor WT may include a write source electrode WS, a write channel layer W-CH, a write gate electrode WG, and a write drain electrode WD. The write source electrode WS may be a part of the write bit line W-BL. The write bit line W-BL may have a line shape extending in a first horizontal direction X. The write channel layer W-CH may be disposed on the write source electrode WS in a pillar shape extending in a vertical direction Z. The write gate electrode WG may surround side surfaces of the write channel layer W-CH. For example, the write channel layer W-CH may vertically pass through the write gate electrode WG. Therefore, the write transistor WT may have a gate-all-around (GAA) channel structure. The write gate electrode WG may be a part of the write word line W-WL. The write word line W-WL may have a line shape extending in a second horizontal direction Y. The first horizontal direction X and the second horizontal direction Y may be perpendicular to each other. The write drain electrode WD may be disposed on the write channel layer W-CH. The write channel layer W-CH and the write drain electrode WD may form a pillar shape.

The read transistor RT may include a read gate electrode RG, a storage node SN, a read channel layer R-CH, a read source electrode RS, and a read drain electrode RD. The read gate electrode RG may be an element shared with the write drain electrode WD. In an embodiment, the read gate electrode RG may be an element electrically connected to the write drain electrode WD. The storage node SN may be disposed on the read gate electrode RG. For example, the storage node SN may be a gate dielectric layer of the read transistor RT. The read channel layer R-CH may be disposed on the storage node SN in a pillar shape. The read source electrode RS may be disposed to be adjacent to or in contact with a first side surface of the read channel layer R-CH. For example, the read source electrode RS may partially surround the first side surface of the read channel layer R-CH. The read source electrode RS may be a part of the read word line R-WL. The read word line R-WL may have a line shape extending in the first horizontal direction X. The read drain electrode RD may be disposed to be adjacent to or in contact with a second side surface of the read channel layer R-CH. For example, the read drain electrode RD may partially surround the second side surface of the read channel layer R-CH. The first side surface and the second side surface may be opposite to each other. The read drain electrode RD may be a part of the read bit line R-BL. The read bit line R-BL may extend in the first horizontal direction X. The read word line R-WL and the read bit line R-BL may be parallel to each other. The write channel layer W-CH, the write drain electrode WD and/or the read gate electrode RG, the storage node SN, and the read channel layer R-CH may form a circular pillar shape or a polygonal pillar shape.

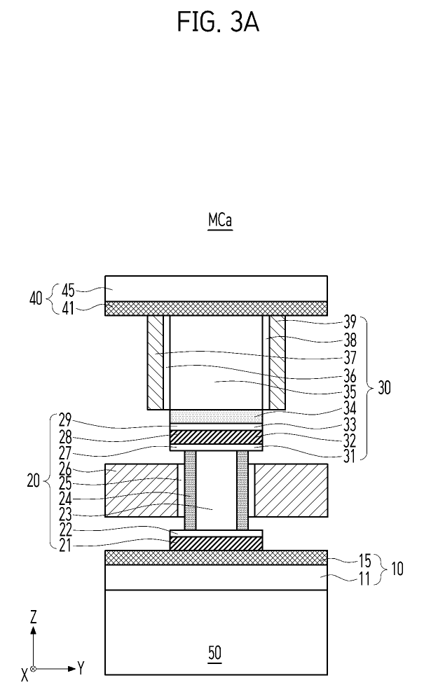

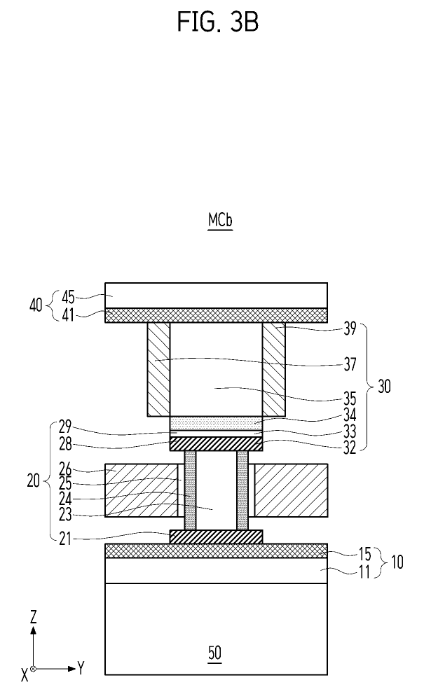

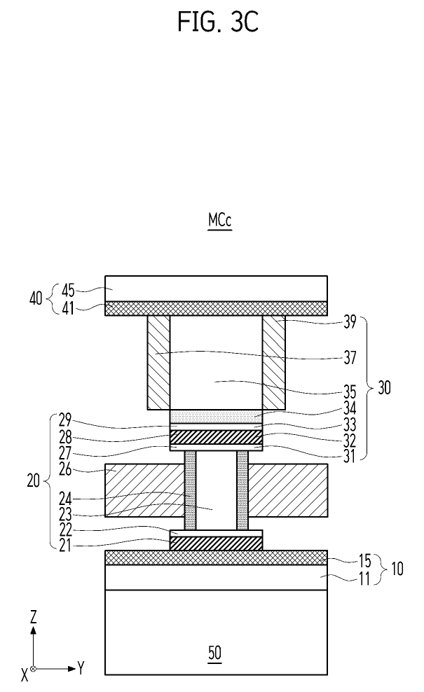

FIGS. 3A-3C are longitudinal cross-sectional views schematically illustrating memory cells MCa-MCc of capacitorless semiconductor memory devices according to embodiments of the present disclosure. Referring to FIGS. 3A-3C, each of the memory cells MCa-MCc of the capacitorless semiconductor memory devices may include an underlying layer 50, a lower insulating layer 10 disposed over the underlying layer 50, a write transistor 20 disposed over the lower insulating layer 10, a read transistor 30 disposed over the write transistor 20, and an upper insulating layer 40 disposed over the read transistor 30. The underlying layer 50 may include an insulating layer based on a silicon oxide. In an embodiment, the underlying layer 50 may include a peripheral circuit layer.

The lower insulating layer 10 may include a first lower insulating layer 11 and a second lower insulating layer 15 disposed over the first lower insulating layer 11. The first lower insulating layer 11 may include one of an insulating layer based on silicon oxide, an insulating layer based on silicon nitride, or an insulating layer based on silicon oxide nitride. In an embodiment, the first lower insulating layer 11 may be a part of the underlying layer 50. The second lower insulating layer 15 may include an insulating material layer having a higher work function and a higher energy barrier level than the first lower insulating layer 11. In an embodiment, the second lower insulating layer 15 may include an insulating metal compound layer. For example, the second lower insulating layer 15 may include at least one of an aluminum oxide (AlO) layer, a hafnium oxide (HfO) layer, a zirconium oxide (ZrO) layer, a zinc oxide (ZnO) layer, a titanium oxide (TiO) layer, or a molybdenum oxide (MoO) layer. The second lower insulating layer 15 may be disposed closer to the write transistor 20 than the first lower insulating layer 11.

The upper insulating layer 40 may include a first upper insulating layer 41 and a second upper insulating layer 45 disposed over the first insulating layer 41. The first upper insulating layer 41 may include an insulating material layer having a higher work function and a higher energy barrier level than the second upper insulating layer 45. In an embodiment, the first upper insulating layer 41 may include an insulating metal compound layer. For example, the first upper insulating layer 41 may include at least one of an aluminum oxide (AlO) layer, a hafnium oxide (HfO) layer, a zirconium oxide (ZrO) layer, a zinc oxide (ZnO) layer, a titanium oxide (TiO) layer, or a molybdenum oxide (MoO) layer. The second upper insulating layer 45 may include one of an insulating layer based on silicon oxide, an insulating layer based on silicon nitride, or an insulating layer based on silicon oxynitride. The first upper insulating layer 41 may be disposed closer to the read transistor 30 than the second upper insulating layer 45.

Referring to FIG. 3A, the write transistor 20 of the memory cell MCa may include a write source electrode 21, a write source electrode barrier layer 22, a write channel layer 23, a write gate dielectric layer 24, a write gate electrode barrier layer 25, a write gate electrode 26, a write drain electrode lower barrier layer 27, a write drain electrode 28, and a write drain electrode upper barrier layer 29.

The write source electrode 21 may be disposed on the lower insulating layer 10. The write source electrode 21 may be a part of the write bit line W-BL having a line shape extending in the first horizontal direction X.

The write source electrode barrier layer 22 may be disposed on the write source electrode 21. The write source electrode barrier layer 22 may also be a part of the write bit line W-BL and may extend in the first horizontal direction X. For example, the write bit line W-BL may be a double layer having a write bit line electrode layer and a write bit line electrode barrier layer.

The write channel layer 23 may be disposed over the write source electrode 21 and the write source electrode barrier layer 22, and may have a circular pillar shape or a polygonal pillar shape extending in the vertical direction Z.

The write gate dielectric layer 24 may surround a side surface of the write channel layer 23. The write gate dielectric layer 24 may have a ring shape or a cylinder shape. Top and bottom surfaces of the write channel layer 23 and the write gate dielectric layer 24 may be coplanar, respectively. The write gate dielectric layer 24 may be disposed between the write channel layer 23 and the write gate electrode barrier layer 25.

The write gate electrode barrier layer 25 may surround a side surface of the write gate dielectric layer 24. The write gate electrode barrier layer 25 may have a ring shape or a cylinder shape. The write gate electrode barrier layer 25 may be disposed between the write gate dielectric layer 24 and the write gate electrode 26.

The write gate electrode 26 may surround a side surface of the write gate electrode barrier layer 25. The write gate electrode 26 may be a part of a line-shaped write word line W-WL extending in the second horizontal direction Y. The write channel layer 23, the write gate dielectric layer 24, and the write gate electrode barrier layer 25 may vertically pass through the write gate electrode 26. Top and bottom surfaces of the write gate electrode barrier layer 25 and the write gate electrode 26 may be coplanar, respectively.

The write drain electrode lower barrier layer 27 may be disposed over the write channel layer 23 to have a pad shape. The write drain electrode lower barrier layer 27 may be in contact with the write channel layer 23 and the write gate dielectric layer 24, and may be spaced apart from the write gate electrode barrier layer 25 and the write gate electrode 26.

The write drain electrode 28 may be disposed over the write drain electrode lower barrier layer 27 to have a pad shape. The write drain electrode 28 may be in contact with the write drain electrode lower barrier layer 27.

The write drain electrode upper barrier layer 29 may be disposed over the write drain electrode 28 to have a pad shape. The write drain electrode upper barrier layer 29 may be in contact with the write drain electrode 28. Side surfaces of the write drain electrode lower barrier layer 27, the write drain electrode 28, and the write drain electrode upper barrier layer 29 may be vertically coplanar.

The read transistor 30 may include a read gate electrode lower barrier layer 31, a read gate electrode 32, a read gate electrode upper barrier layer 33, a storage node 34, a read channel layer 35, a read source electrode barrier layer 36, a read source electrode 37, a read drain electrode barrier layer 38, and a read drain electrode 39.

The read gate electrode lower barrier layer 31 may be shared with the write drain electrode lower barrier layer 27. For example, the read gate electrode lower barrier layer 31 may be the same element as the write drain electrode lower barrier layer 27. Accordingly, the write transistor 20 and the read transistor 30 may share the element corresponding to (i.e., that functions as) the write drain electrode lower barrier layer 27 and the read gate electrode lower barrier layer 31. Thus, the read gate electrode lower barrier layer 31 may be disposed over the write channel layer 23 and the write gate dielectric layer 24 to have a pad shape, may be in contact with the top surfaces of the write channel layer 23 and the write gate dielectric layer 24, and may be spaced apart from the write gate electrode barrier layer 25 and the write gate electrode 26.

The read gate electrode 32 may be shared with the write drain electrode 28. For example, the read gate electrode 32 may be the same element as the write drain electrode 28. Accordingly, the write transistor 20 and the read transistor 30 may share the element corresponding to the write drain electrode 28 and the read gate electrode 32. Thus, the read gate electrode 32 may be disposed over the read gate electrode lower barrier layer 31 to have a pad shape. The read gate electrode 32 may be in contact with the read gate electrode lower barrier layer 31.

The read gate electrode upper barrier layer 33 may be shared with the write drain electrode upper barrier layer 29. For example, the read gate electrode upper barrier layer 33 may be the same element as the write drain electrode upper barrier layer 29. Accordingly, the write transistor 20 and the read transistor 30 may share the element corresponding to the write drain electrode upper barrier layer 29 and the read gate electrode upper barrier layer 33. Thus, the read gate electrode upper barrier layer 33 may be disposed over the read gate electrode 32 to have a pad shape. The read gate electrode upper barrier layer 33 may be in contact with the read gate electrode 32. Side surfaces of the read gate electrode lower barrier layer 31, the read gate electrode 32, and the read gate electrode upper barrier layer 33 may be vertically coplanar. In an embodiment, the read gate electrode 32 may be an additional element disposed over the write drain electrode 28 and electrically connected to the write drain electrode 28.

The storage node 34 may be disposed over the read gate electrode upper barrier layer 33. For example, the storage node 34 may be a read gate dielectric layer disposed between the read gate electrode 31 and the read channel layer 35.

The read channel layer 35 may be disposed on the storage node 34 to have a pillar shape.

The read source electrode barrier layer 36 may be disposed to be adjacent to or in contact with a first side surface of the read channel layer 35. For example, an inner side surface of the read source electrode barrier layer 36 may partially surround the first side surface of the read channel layer 35.

The read source electrode 37 may be disposed to be adjacent to or in contact with a side surface of the read source electrode barrier layer 36. For example, the inner side of the read source electrode 37 may be adjacent to or in contact with an outer side of the read source electrode barrier layer 36. The read source electrode 37 may be a part of the read word line R-WL extending in the first horizontal direction X.

In an embodiment, the read source electrode barrier layer 36 may also be a part of the read word line R-WL. For example, the read word line R-WL may be a double layer having a read source electrode layer and a read source electrode barrier layer. Top and bottom surfaces of the read source electrode barrier layer 36 and the read source electrode 37 may be coplanar, respectively.

The read drain electrode barrier layer 38 may be disposed to be adjacent to or in contact with a second side surface of the read channel layer 35. For example, an inner side surface of the read drain electrode barrier layer 38 may partially surround the second side surface of the read channel layer 35. The first side surface and the second side surface of the read channel layer 35 may be opposite to each other.

The read drain electrode 39 may be disposed to be adjacent to or in contact with a side surface of the read drain electrode barrier layer 38. For example, the inner side of the read drain electrode 39 may be adjacent to or in contact with an outer side of the read drain electrode barrier layer 38. The read drain electrode 39 may be a part of the read bit line R-BL extending in the first horizontal direction X.

In an embodiment, the read drain electrode barrier layer 38 may also be a part of the read bit line R-BL. For example, the read bit line R-BL may be a double layer having a read drain electrode layer and a read drain electrode barrier layer. Top and bottom surfaces of the read drain electrode barrier layer 38 and the read drain electrode 39 may be coplanar, respectively.

Referring to FIG. 3B, a write transistor 20 of the memory cell MCb may include a write source electrode 21, a write channel layer 23, a write gate dielectric layer 24, a write gate electrode barrier layer 25, a write gate electrode 26, a write drain electrode 28, and a write drain electrode upper barrier layer 29, and a read transistor 30 may include a read gate electrode 32, a read gate electrode upper barrier layer 33, a storage node 34, a read channel layer 35, a read source electrode 37, and a read drain electrode 39.

The write source electrode 21 may be in contact with lower ends of the write channel layer 23 and the write gate dielectric layer 24. The write drain electrode 28 or the read gate electrode 32 may be in contact with top ends of the write channel layer 23 and the write gate dielectric layer 24.

The read source electrode 37 may be adjacent to or in contact with a first side surface of the read channel layer 35. For example, the read source electrode 37 may partially surround the first side surface of the read channel layer 35.

The read drain electrode 39 may be adjacent to or in contact with a second side surface of the read channel layer 35. For example, the read drain electrode 39 may partially surround the second side surface of the read channel layer 35.

The write drain electrode 28 and the read gate electrode 32 may be the same element shared by the write transistor 20 and the read transistor 30, and the write drain electrode upper barrier layer 29 and the read gate electrode upper barrier layer 33 may be the same element shared by the write transistor 20 and the read transistor 30.

Referring to FIG. 3C, a write transistor 20 of the memory cell MCc may include a write source electrode 21, a write source electrode barrier layer 22, a write channel layer 23, a write gate dielectric layer 24, a write gate electrode 26, a write drain electrode lower barrier layer 27, a write drain electrode 28, and a write drain electrode upper barrier layer 29, and a read transistor 30 may include a read gate electrode lower barrier layer 31, a read gate electrode 32, a read gate electrode upper barrier layer 33, a storage node 34, a read channel layer 35, a read source electrode 37, and a read drain electrode 39.

The write gate electrode 26 may be in contact with the write gate dielectric layer 24. The read source electrode 37 may be adjacent to or in contact with the first side surface of the read channel layer 35. The read drain electrode 39 may be adjacent to or in contact with the second side surface of the read channel layer 35.

The write drain electrode lower barrier layer 27 and the read gate electrode lower barrier layer 31 may be the same element shared by the write transistor 20 and the read transistor 30, the write drain electrode 28 and the read gate electrode 32 may be the same element shared by the write transistor 20 and the read transistor 30, and the write drain electrode upper barrier layer 29 and the read gate electrode upper barrier layer 33 may be the same element shared by the write transistor 20 and the read transistor 30.

Each of the write transistor 20 and the read transistor 30 may include thin film transistors (TFT).

Each of the write channel layer 23 and the read channel layer 35 may include at least one of a doped polysilicon, a metal oxide layer, or a two-dimensional transition metal chalcogenide material layer. The metal oxide layer may include at least one of an indium oxide (In₂O₃) layer, a titanium (Ti)-doped indium oxide layer, a tungsten (W)-doped indium oxide layer, a silicon (Si)-doped indium oxide layer, an IGZO (InGaZnO, for example amorphous indium-gallium-zinc oxide), an SGZO (SnGaZnO), ZnO, or IGO (InGaO). The two-dimensional transition metal chalcogenide material layer may include at least one of MoS (for example, molybdenum disulfide (MoS₂)), WS (for example, tungsten disulfide (WS₂)), WSe (for example, tungsten diselenide (WSe₂)), or MoSe (for example, molybdenum diselenide (MoSe₂)). In an embodiment, the write channel layer 23 and the read channel layer 35 may include an oxide semiconductor such as IGZO. The oxide semiconductors can have N-type semiconductor characteristics and may have advantageous properties due to wider band gap, better thermal stability, high mobility, low-temperature process, and sufficient oxygen vacancies than silicon semiconductors.

The write gate dielectric layer 24 and the storage node 34 may include at least one of a silicon oxide layer, a silicon nitride layer, or a high-k dielectric layer such as a metal oxide layer. The metal oxide layer may include at least one of a hafnium oxide (HfO) layer, a zirconium oxide (ZnO) layer, or an aluminum oxide (AlO) layer.

Each of the write source electrode 21, the write gate electrode 26, the write drain electrode 28 or the read gate electrode 32, the read source electrode 37, and the read drain electrode 39 may include at least one of doped polysilicon(Si), a metal (such as tungsten(W), platinum(Pt), gold(Au), palladium(Pd), molybdenum(Mo), nickel(Ni), silver(Ag), or copper(Cu)), or a metal compound (such as titanium nitride(TiN), tantalum nitride(TaN), or tungsten nitride(WN), a metal silicide, and a metal alloy).

The write source electrode barrier layer 22, the write gate electrode barrier layer 25, the write drain electrode lower barrier layer 27 or the read gate electrode lower barrier layer 31, the write drain electrode upper barrier layer 29 or the read gate electrode upper barrier layer 33, the read source electrode barrier layer 36, and the read drain electrode barrier layer 38 may include conductive carbon layers – e.g., graphene layers, respectively. The graphene layer may screen hydrogen atoms or hydrogen ions. Thus, barrier layers 22, 25, 27, 29, 31, 33, 36, and 38 including the graphene layer may prevent diffusing, entering, penetrating, or moving of hydrogen atoms or hydrogen ions into write and read channel layers 23 and 35. The barrier layers 22, 25, 27, 29, 31, 33, 36, and 38 may include at least one of the write source electrode barrier layer 22, the write gate electrode barrier layer 25, the write drain electrode lower barrier layer 27, the write drain electrode upper barrier layer 29, the read gate electrode lower barrier layer 31, the read gate electrode upper barrier layer 33, the read source electrode barrier layer 36, or the read drain electrode barrier layer 38.

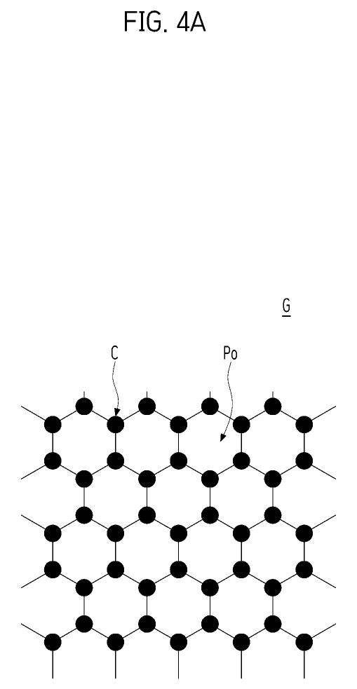

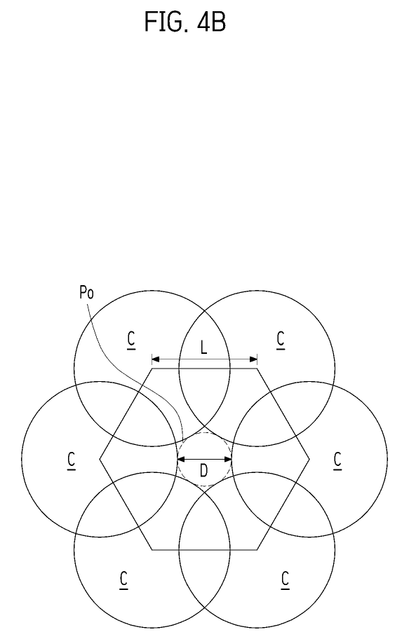

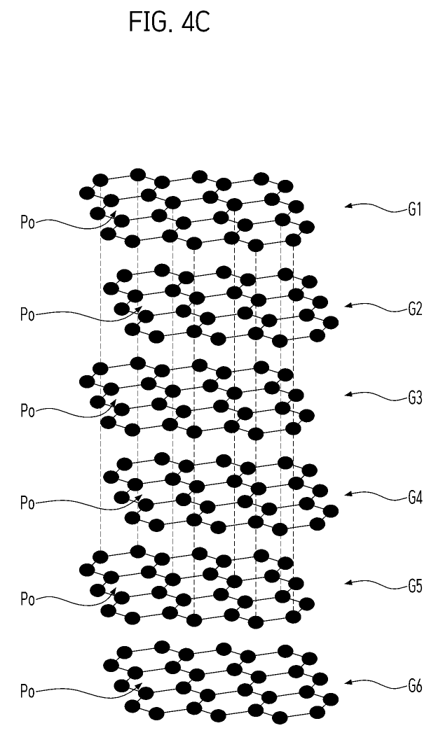

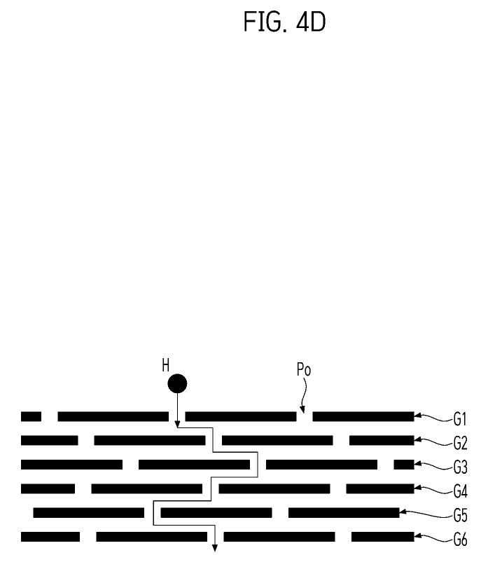

FIGS. 4A-4C are diagrams illustrating the barrier layers 22, 25, 27, 29, 31, 33, 36, and 38 according to embodiments of the present disclosure. Referring to FIG. 4A, the barrier layers 22, 25, 27, 29, 31, 33, 36, and 38 may include a graphene layer G. Referring to FIG. 4A, the graphene layer G may include carbon atoms C covalently bonded in a hexagonal honeycomb structure to form a plurality of pores Po. Referring to FIG. 4B, in the graphene layer, a bonding length L between adjacent central points of carbon atoms C is about 0.142 nm, and a width or diameter D of a pore Po formed by six carbon atoms C is about 0.064 nm. Referring to FIG. 4C, the barrier layers 22, 25, 27, 29, 31, 33, 36, and 38 may include multiple graphene layers G1 to G5 that are stacked with an offset. For example, the graphene layers may be stacked with an offset so that the adjacent pores Po are not vertically aligned.

FIG. 4D is a conceptual diagram illustrating hydrogen atoms H passing through the pores Po of the stacked graphene layers G1 to G6. Since the graphene layers G1 to G6 are stacked with an offset so that the pores Po are not vertically aligned, it is very difficult to pass through the stacked graphene layers G1 to G6 in which hydrogen atoms H due to the lengthened penetration path.

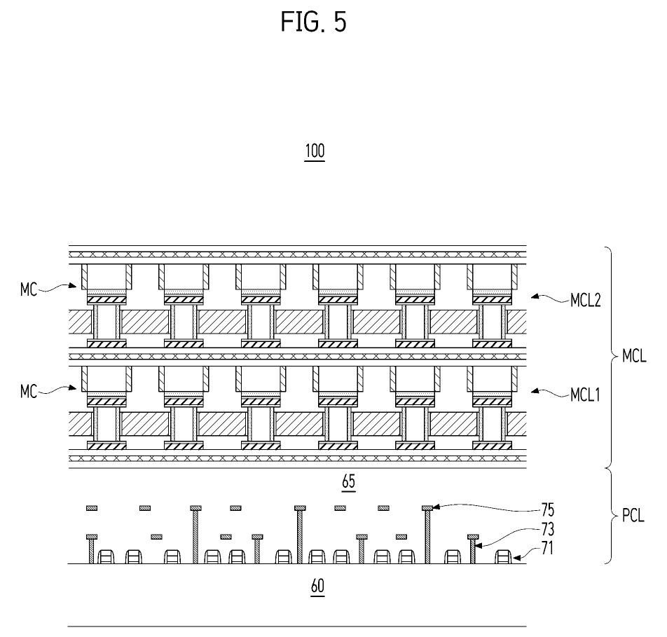

FIG. 5 is a longitudinal cross-sectional view schematically illustrating a capacitorless semiconductor memory device 100 according to an embodiment of the present disclosure. Referring to FIG. 5, the capacitorless semiconductor memory device 100 may include a peripheral circuit layer PCL and a memory cell layer MCL. The memory cell layer MCL may be disposed or stacked over the peripheral circuit layer PCL. The peripheral circuit layer PCL may include transistor structures 71, vertical contact plugs 73, horizontal interconnections 75, and an interlayer insulating layer 65 disposed on a substrate 60. The substrate 60 may include a silicon wafer. The transistors 71, the vertical contact plugs 73, and the horizontal wirings 75 may form sense amplifiers, various logic circuits, voltage generators, internal signal generators, and input/output buffers. Each of the vertical contact plugs 73 and the horizontal interconnections 75 may include a conductor such as a metal. The interlayer insulating layer 65 may include at least one of a silicon oxide-based insulating layer, a silicon nitride-based insulating layer, or a silicon oxynitride-based insulating layer. The peripheral circuit layer PCL may be included in the underlying layer 50 of FIGS. 3A-3C. The memory cell layer MCL may include at least one of a plurality of memory cell layers MCL1 and MCL2. Each of the memory cell layers MCL1 and MCL2 may include a plurality of memory cells MC disposed in a horizontal direction. Further referring to FIGS. 3A to 3C, the upper insulating layer 40 of the first memory cell layer MCL1 may be common to the lower insulating layer 10 of the second memory cell MCL2. The interlayer insulating layer 65 may cover the transistor structures 71, the vertical contact plugs 73, and the horizontal interconnections 75. The underlying layer 50 may include at least one of the peripheral circuit layer PCL, the substrate 10, or the interlayer insulating layer 65. The underlying layer 50 may include at least one of the peripheral circuit layer PCL, the substrate 60, or the interlayer insulating layer 65.

According to the embodiments of the present disclosure, the graphene layer can block diffusing, entering, penetrating, or moving of hydrogen atoms or hydrogen ions into the channel layers of the transistors during the manufacturing processes and operating. That is, the channel layer of the transistors can be protected from the hydrogen doping effect. Accordingly, a resistance, a threshold voltage, and a channel generation of the channel layers of the transistors can be stabilized, and chemical and material stability can be improved. In particular, a threshold voltage shift phenomenon of the channel layers in a high-temperature positive voltage bias state can be improved.

While the present disclosure has been described with respect to specific embodiments, it will be apparent to those skilled in the art that various changes and modifications may be made without departing from the technical concepts and scope of the disclosure as defined in the following claims. Furthermore, the embodiments may be combined to form additional embodiments.

What is claimed is:

1. A capacitorless semiconductor memory device comprising:
an underlying layer;
a lower insulating layer disposed over the underlying layer;
a write transistor disposed over the lower insulating layer;
a read transistor disposed over the write transistor; and
an upper insulating layer disposed over the read transistor,
wherein the write transistor includes:
a write source electrode;
a write channel layer disposed over the write source electrode;
a write gate dielectric layer disposed to surround a side surface of the write channel layer;
a write gate electrode disposed to surround a side surface of the write gate dielectric layer;
a write drain electrode disposed over the write channel layer; and
a write drain electrode upper barrier layer disposed over the write drain electrode, the write drain electrode upper barrier layer including a carbon layer.

2. The capacitorless semiconductor memory device of claim 1, wherein the carbon layer includes a plurality of graphene layers.

3. The capacitorless semiconductor memory device of claim 2, wherein the plurality of graphene layers are stacked with an offset.

4. The capacitorless semiconductor memory device of claim 1, further comprising a write drain electrode lower barrier layer disposed between the write channel layer and the write drain electrode.

5. The capacitorless semiconductor memory device of claim 1, further comprising a write source electrode barrier layer disposed between the write source electrode and the write channel layer.

6. The capacitorless semiconductor memory device of claim 1, further comprising a write gate electrode barrier layer disposed between the write gate dielectric layer and the write gate electrode.

7. The capacitorless semiconductor memory device of claim 1, wherein the read transistor includes:
a read gate electrode shared with the write drain electrode;
a read gate electrode upper barrier layer shared with the write drain electrode upper barrier layer;
a read gate dielectric layer disposed over the read gate electrode upper barrier layer;
a read channel layer disposed over the read gate dielectric layer;
a read source electrode disposed to be adjacent to a first side surface of the read channel layer; and
a read drain electrode disposed to be adjacent to a second side surface of the read channel layer.

8. The capacitorless semiconductor memory device of claim 7, further comprising a read source electrode barrier layer disposed between the read channel layer and the read source electrode.

9. The capacitorless semiconductor memory device of claim 7, further comprising a read drain electrode barrier layer disposed between the read channel layer and the read drain electrode.

10. The capacitorless semiconductor memory device of claim 1,
wherein the lower insulating layer includes:
a first lower insulating layer; and
a second lower insulating layer disposed over the first lower insulating layer,
wherein the first lower insulating layer includes at least one of a silicon oxide-based insulating layer, a silicon nitride-based insulating layer, or a silicon oxynitride-based insulating layer, and
wherein the second lower insulating layer includes an insulating metal compound layer having a higher work function and a higher energy barrier level than the first lower insulating layer.

11. The capacitorless semiconductor memory device of claim 10, wherein the second lower insulating layer includes a metal oxide layer including at least one of aluminum, hafnium, zirconium, zinc, titanium, or molybdenum.

12. The capacitorless semiconductor memory device of claim 1,
wherein the upper insulating layer includes:
a first upper insulating layer; and
a second upper insulating layer disposed over the first upper insulating layer,
wherein the first upper insulating layer includes an insulating metal compound layer, and
wherein the second upper insulating layer includes at least one of a silicon oxide-based insulating layer, a silicon nitride-based insulating layer, or a silicon oxynitride-based insulating layer.

13. The capacitorless semiconductor memory device of claim 12, wherein the first upper insulating layer includes a metal oxide layer including at least one of aluminum, hafnium, zirconium, zinc, titanium, or molybdenum.

14. The capacitorless semiconductor memory device of claim 1, wherein the write source electrode is a part of a write bit line disposed to extend in a first horizontal direction.

15. The capacitorless semiconductor memory device of claim 14, wherein the write gate electrode is a part of a write word line disposed to extend in a second horizontal direction perpendicular to the first horizontal direction.

16. The capacitorless semiconductor memory device of claim 14,
wherein the read source electrode is a part of a read word line disposed to extend in the first horizontal direction,
wherein the read drain electrode is a part of a read bit line disposed to extend in the first horizontal direction, and
wherein the read word line and the read bit line extend parallel to each other.

17. The capacitorless semiconductor memory device of claim 1,
wherein the write channel layer and the write gate dielectric layer have a pillar shape vertically passing through the write gate electrode.

18. The capacitorless semiconductor memory device of claim 1,
wherein the underlying layer includes a peripheral circuit layer, and
wherein the peripheral circuit layer includes transistors, vertical contact plugs, and horizontal interconnections, which are disposed over a substrate.

19. A capacitorless semiconductor memory device comprising:
a lower insulating layer;
a write transistor disposed over the lower insulating layer;
a read transistor disposed over the write transistor; and
an upper insulating layer disposed over the read transistor,
wherein the read transistor includes:
a read gate electrode disposed over a write channel layer of the write transistor;
a read gate electrode upper barrier layer disposed over the read gate electrode, the read gate electrode upper barrier layer including a graphene layer;
a read gate dielectric layer disposed over the read gate electrode upper barrier layer;
a read channel layer disposed over the read gate dielectric layer;
a read source electrode disposed to be adjacent to a first side of the read channel layer; and
a read drain electrode disposed to be adjacent to a second side surface of the read channel layer.

20. A capacitorless semiconductor memory device comprising:
a peripheral circuit layer including transistors, vertical contact plugs, and horizontal interconnections, which are disposed over a substrate; and
a memory cell layer disposed over the peripheral circuit layer, the memory cell layer including at least one memory cell layer in which a plurality of memory cells are arranged,
wherein each of the memory cells includes:
a lower insulating layer;
a write transistor disposed over the lower insulating layer;
a read transistor disposed over the write transistor; and
an upper insulating layer disposed over the read transistor,
wherein the write transistor includes:
a write source electrode disposed over the lower insulating layer;
a write channel layer disposed over the write source electrode:
a write gate dielectric layer disposed to surround a side surface of the write source electrode;
a write gate electrode disposed to surround a side surface of the write gate dielectric layer;
a write drain electrode disposed over the write channel layer; and
a graphene layer disposed between the write channel layer and the write drain electrode, or between the write drain electrode and the read transistor.
